(19) United States
(12) Patent Application Publication
(10) Pub. No.: US 2025/0201289 A1
(43) Pub. Date: Jun. 19, 2025

(54) HIGH-BANDWIDTH MEMORY DEVICE AND OPERATION METHOD THEREOF

(71) Applicant: Samsung Electronics Co., Ltd., Suwon-si (KR)

(72) Inventor: Jongpil SON, Suwon-si (KR)

(21) Appl. No.: 18/670,875

(22) Filed: May 22, 2024

(30) Foreign Application Priority Data
Dec. 14, 2023 (KR) 10-2023-0182026

(51) Int. Cl. G11C 8/18; G11C 7/10

(52) U.S. Cl. CPC G11C 8/18; G11C 7/1039; G11C 7/1048; G11C 7/1069

(57) ABSTRACT

Disclosed is an operation method of a high bandwidth memory (HBM) device which includes receiving a mode register set (MRS) command through row command/address signal lines in an idle mode, performing an MRS operation in response to the MRS command, receiving an activate (ACT) command through the row command/address signal lines in the idle mode, and switching to an activate mode in response to the ACT command. Switching to the activate mode includes switching one or more memory buffers of the HBM device to an active state.

### CROSS-REFERENCE TO RELATED APPLICATIONS

This application claims priority under 35 U.S.C. § 119 to Korean Patent Application No. 10-2023-0182026 filed on Dec. 14, 2023, in the Korean Intellectual Property Office, the disclosures of which are incorporated by reference herein in their entireties.

### BACKGROUND

Embodiments of the present disclosure described herein relate to a semiconductor memory, and more particularly, relate to a high-bandwidth memory device and an operation method thereof.

As the speed of a central processing unit (CPU) increases and the use of a graphics processing unit (GPU) or a natural processing unit (NPU) increases, a high-bandwidth memory device capable of coinciding with speeds thereof is increasingly desired. A typical example of the high-bandwidth memory device is a high-bandwidth memory (HBM) device. The high-bandwidth memory device may have a higher bandwidth than a conventional memory device and may provide data to coincide with operating speeds of the processors described above.

As the bandwidth of the high-bandwidth memory device gradually increases, the number of channels in the memory device may increase. To cope with the above issue, the number of command/address (CA) buffers which are provided within memory device channels to provide a command may increase. As the number of CA buffers increases, a current consumption amount of the CA buffers increases. Accordingly, it is desired to reduce the current amount to improve the performance of the memory device.

### SUMMARY

Embodiments of the present disclosure provide a memory system capable of improving the performance of a memory device by reducing the amount of current which the memory device uses.

According to some embodiments, an operation method of a high bandwidth memory (HBM) device includes receiving a mode register set (MRS) command through row command/address signal lines in an idle mode, performing an MRS operation in response to the MRS command, receiving an activate (ACT) command through the row command/address signal lines in the idle mode, and switching to an activate mode in response to the ACT command, wherein switching to the activate mode includes switching one or more memory buffers of the HBM device to an active state.

According to some embodiments, an operation method of an high bandwidth memory (HBM) device includes selecting one of a first mode and a second mode in an idle mode, in which a column command/address (CA) buffer configured to buffer a column command/address signal is in an inactive state in the first mode and is in an active state in the second mode, performing an mode register set (MRS) operation in the idle mode, and receiving an activate (ACT) command through a row command/address signal line and switching to activate mode in response to the ACT command, in the idle mode, wherein switching to the activate mode includes setting one or more memory buffers of the HBM device to the active state.

According to some embodiments, a high bandwidth memory (HBM) device which is configured to store data includes a row command buffer that buffers a row command/address signal, a column command buffer that buffers a column command/address signal, a command/address (CA) buffer that decodes the row command/address signal and the column command/address signal, and a memory cell array that stores the data, and the HBM device is configured to receive an mode register set (MRS) command and an activate (ACT) command through the row command/address signal, and the ACT command indicates switching one or more memory buffers of the HBM device to active state.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system according to some embodiments of the present disclosure.

FIG. 2 is a block diagram illustrating a memory device of FIG. 1 in detail, according to some embodiments of the present disclosure.

FIG. 3 is a diagram illustrating a structure of a memory device of FIG. 2, according to some embodiments of the present disclosure.

FIG. 4A is a diagram illustrating an example of a row command truth table of a memory system of FIG. 1, according to some embodiments of the present disclosure.

FIG. 4B is a diagram illustrating an example of a column command truth table of a memory system of FIG. 1, according to some embodiments of the present disclosure.

FIG. 5A is a block diagram illustrating a command/address (CA) unit of FIG. 1 in an idle mode of a memory device, according to some embodiments of the present disclosure.

FIG. 5B is a block diagram illustrating a CA unit of FIG. 1 in an activate mode of a memory device, according to some embodiments of the present disclosure.

FIG. 6 is a flowchart illustrating an operation sequence of a memory system of FIG. 1, according to some embodiments of the present disclosure.

FIG. 7 is a diagram illustrating an example of row command truth table, according to some embodiments of the present disclosure.

FIG. 8 is a block diagram illustrating a CA decoder of FIG. 1 in detail, according to some embodiments of the present disclosure.

FIG. 9 is a diagram illustrating an example of a truth table of a row command truth table of a memory system of FIG. 1 including a CA decoder, according to some embodiments of the present disclosure.

FIG. 10 is a block diagram illustrating a CA decoder of FIG. 1 in detail, according to some embodiments of the present disclosure.

FIG. 11 is a flowchart illustrating an operation sequence of a memory system of FIG. 1, according to some embodiments of the present disclosure.

FIG. 12 is a block diagram illustrating an electronic system according to some embodiments of the present disclosure.

### DETAILED DESCRIPTION

Below, embodiments of the present disclosure will be described in detail and clearly to such an extent that an ordinary one in the art easily carries out the present disclosure.

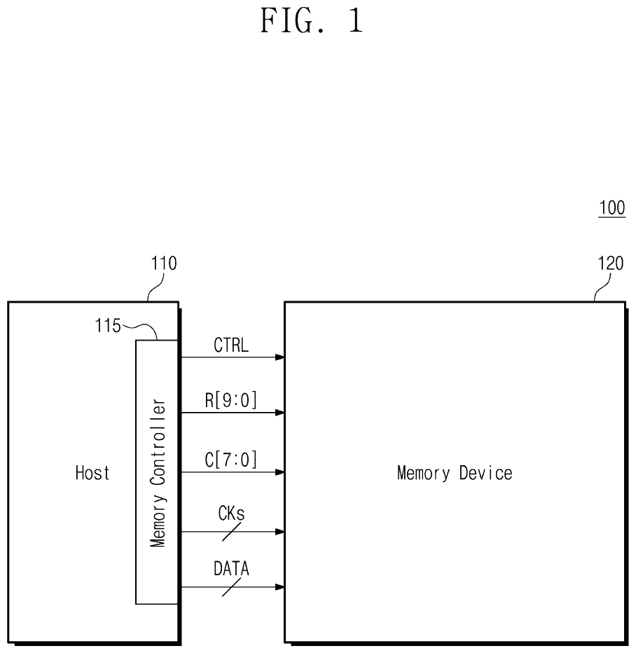

FIG. 1 is a block diagram illustrating a memory system according to some embodiments of the present disclosure. Referring to FIG. 1, a memory system 100 may include a host 110 and a memory device 120, and the host 110 may include a memory controller 115. Operations of the memory system 100 according to some embodiments of the present disclosure will be described with reference to FIG. 1.

The memory system 100 may store data, may manage the stored data, and may provide information necessary for the user. In some embodiments, the memory system 100 may be included in an electronic device such as a personal computer (PC), a laptop computer, a tablet PC, a personal digital assistant (PDA), a wearable device, or a camera. However, this is provided as an example, and the present disclosure is not limited to the case where the memory system 100 is included in the above electronic devices.

The host 110 may exchange data with the memory device 120. In some embodiments, the host 110 may transmit a request to the memory device 120 and may receive a response corresponding to the request from the memory device 120. For example, the host 110 may transmit a request through the memory controller 115 and may receive a response corresponding to the request (e.g., data corresponding to the request) through the memory controller 115. FIG. 1 shows some embodiments in which the host 110 is included in the memory system 100, but it should be understood that various embodiments in which the host 110 is located outside the memory system 100 belongs to the scope and spirit of the invention.

The memory controller 115 may control the memory device 120. In some embodiments, the memory controller 115 may control the memory device 120 based on a plurality of signals. For example, the memory controller 115 may control the memory device 120 based on a row command/address (CA) signal R[9:0], a column command/address (CA) signal C[7:0], or a control signal CTRL. A command/address signal may indicate the row command/address signal R[9:0] or the column command/address signal C[7:0]. In some embodiments, the memory controller 115 may provide the memory device 120 with clocks CKs necessary for an operation of the memory device 120. For example, the memory controller 115 may provide two clocks CKs (e.g., CK_c and CK_t) necessary for the operation of the memory device 120.

In some embodiments, the memory controller 115 may exchange data “DATA” with the memory device 120. For example, in response to a request of the host 110, the memory controller 115 may write the data “DATA” in the memory device 120 or may read the data “DATA” from the memory device 120. FIG. 1 shows some embodiments in which the memory controller 115 is included in the host 110, but it should be understood that some embodiments in which the memory controller 115 is located outside the host 110 also belongs to the scope and spirit of the invention.

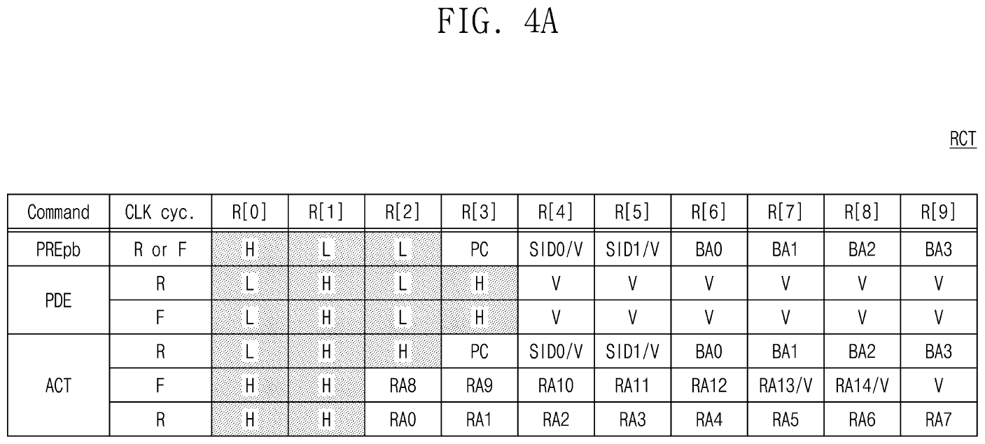

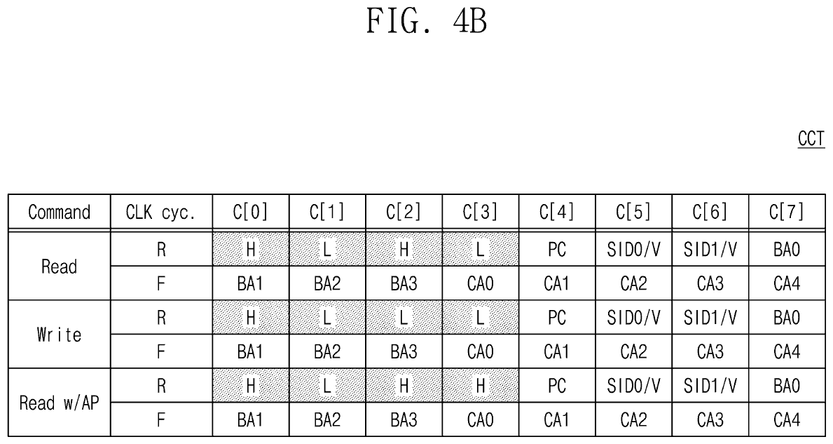

The memory device 120 may store data of the memory system 100. In some embodiments, the memory device 120 may operate under control of the memory controller 115. For example, the memory device 120 may operate in response to the row command/address signal R[9:0], the column command/address signal C[7:0], and the control signal CTRL of the memory controller 115. The row command/address signal R[9:0] will be described in detail with reference to FIG. 4A, and the column command/address signal C[7:0] will be described in detail with reference to FIG. 4B. In some embodiments, the memory device 120 may operate in synchronization with the host 110 or the memory controller 115. For example, the memory device 120 may operate in synchronization with the clocks CKs received from the memory controller 115.

The memory device 120 may include a plurality of memory channels, and likewise, the host 110 may include a plurality of memory controllers 115. For example, the memory device 120 may include 16 memory channels. Each of the plurality of memory channels of the memory device 120 may correspond to one of the memory controllers 115. For example, one memory channel of the memory device 120 may correspond to one memory controller 115, or one or more memory channels of the memory device 120 may correspond to one memory controller 115. In detail, the memory device 120 may include 16 memory channels, and the host 110 may include 16 memory controllers 115 respectively corresponding to the memory channels.

Below, for convenience of description, the present disclosure will be described based on the memory system 100 in which one memory channel is included in the memory device 120 and the memory controller 115 controls one memory channel, but the present disclosure is not limited thereto. It should be understood that some embodiments of the memory system 100 including the memory device 120 including a plurality of memory channels and the plurality of memory controllers 115 controlling at least one memory channel also belongs to the scope and spirit of the invention.

In some embodiments the memory device 120 may be a high-bandwidth memory device. For example, the memory device 120 may be a high bandwidth memory (HBM) device or may include a HBM. Below, the description will be given based on the case where the memory device 120 is the HBM device, but the present disclosure should not be limited thereto. For example, it should be understood that the technical idea of some embodiments to be described later is able to be applied to another type of memory device.

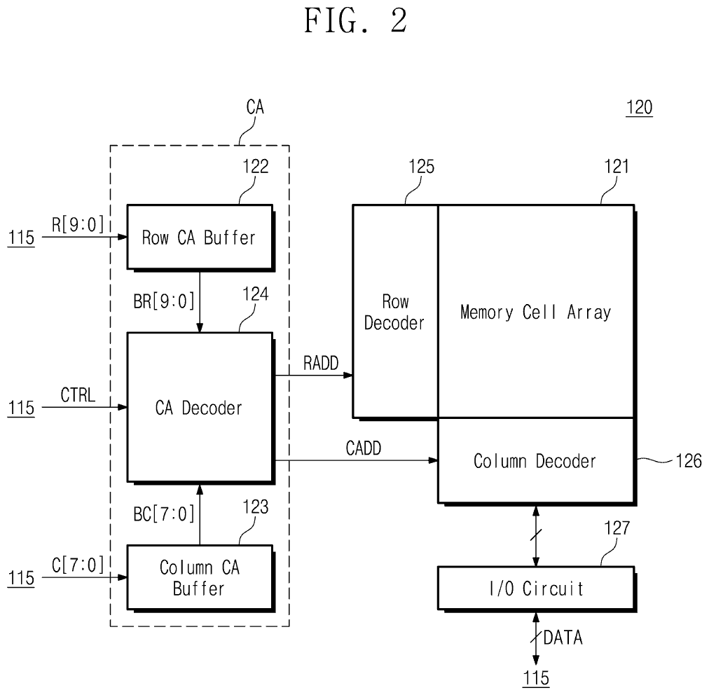

FIG. 2 is a block diagram illustrating a memory device of FIG. 1 in detail, according to some embodiments of the present disclosure. Referring to FIG. 2, the memory device 120 may include a memory cell array 121, a row command/address (CA) buffer 122, a column command/address (CA) buffer 123, a command/address (CA) decoder 124, a row decoder 125, a column decoder 126, and an input/output (I/O) circuit 127. The memory device 120 according to some embodiments of the present disclosure will be described in detail with reference to FIG. 2.

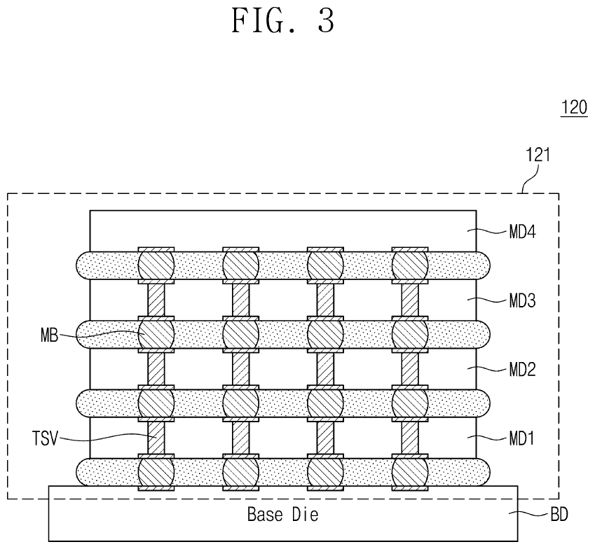

The memory cell array 121 may store data of the memory device 120. In some embodiments, the memory cell array 121 may read or write data depending on an address received from the CA decoder 124. For example, depending on a column address CADD and a row address RADD received from the CA decoder 124, the memory cell array 121 may write data at a relevant location or may read data from a relevant location. A detailed structure of the memory cell array 121 will be described in detail with reference to FIG. 3.

The row CA buffer 122 may receive the row command/address signal R[9:0] from the memory controller 115. In some embodiments, the row CA buffer 122 may buffer the row command/address signal R[9:0]. For example, the row CA buffer 122 may buffer the row command/address signal R[9:0] and may generate a buffered row command/address signal BR[9:0]. The row CA buffer 122 may provide the buffered row command/address signal BR[9:0] to the CA decoder 124. An example in which each of the row command/address signal R[9:0] and the buffered row command/address signal BR[9:0] is a 10-bit signal is illustrated in FIG. 2, but the present disclosure should not be limited thereto. Below, for convenience, the description will be given based on the case where the row command/address signal R[9:0] is a 10-bit signal and the buffered row command/address signal BR[9:0] is also a 10-bit signal.

The column CA buffer 123 may receive the column command/address signal C[7:0] from the memory controller 115. In some embodiments, the column CA buffer 123 may buffer the column command/address signal C[7:0]. For example, the column CA buffer 123 may buffer the column command/address signal C[7:0] and may generate a buffered column command/address signal BC[7:0]. The column CA buffer 123 may provide the buffered column command/address signal BC[7:0] to the CA decoder 124. An example in which each of the column command/address signal C[7:0] and the buffered column command/address signal BC[7:0] is an 8-bit signal is illustrated in FIG. 2, but the present disclosure should not be limited thereto. Below, for convenience, the description will be given based on the case where the column command/address signal C[7:0] is an 8-bit signal and the buffered column command/address signal BC[7:0] is also an 8-bit signal.

The CA decoder 124 may decode a CA signal. A buffered column command/address (CA) signal may indicate the buffered row command/address signal BR[9:0] or the buffered column command/address signal BC[7:0]. The CA decoder 124 may decode the CA signal by decoding the received CA signal. In some embodiments, the CA decoder 124 may decode the buffered CA signals to provide an address value to the memory cell array 121 or to allow the memory device 120 to perform operations indicated by commands received through command signals. For example, the CA decoder 124 may receive and decode the buffered row command/address signal BR[9:0] generated based on the row command/address signal R[9:0] corresponding to a self-refresh command and may allow the memory device 120 to perform a self-refresh operation.

The row decoder 125 may provide the access to row elements of the memory cell array 121. For example, the row decoder 125 may access a row element of the memory cell array 121 based on the row address RADD from the CA decoder 124. The column decoder 126 may provide the access to column elements of the memory cell array 121. For example, the column decoder 126 may access a column element of the memory cell array 121 based on the column address CADD from the CA decoder 124. In some embodiments, the row address RADD or the column address CADD may include information (e.g., a bank address) of a bank in the memory cell array 121, which is to be accessed.

The input/output circuit 127 may control a data input/output of the memory cell array 121. The input/output circuit 127 may provide data (e.g., through the memory controller 115) as a response to the request of the host 110 of FIG. 1. In some embodiments, the input/output circuit 127 may temporarily store data read from the memory cell array 121 or data to be written in the memory cell array 121. For example, the input/output circuit 127 may temporarily store data which are received from the memory controller 115 so as to be written in the memory cell array 121.

FIG. 3 is a diagram illustrating a structure of a memory device of FIG. 2, according to some embodiments of the present disclosure. Referring to FIG. 3, the memory device 120 may include a base die BD and the memory cell array 121. According to some embodiments of the present disclosure, a structure on a semiconductor substrate of the memory device 120 will be described with reference to FIG. 3.

The memory cell array 121 may include memory dies MD1 to MD4 sequentially stacked on the base die BD in a vertical direction that is perpendicular to the top surface of the base die BD. The memory dies MD1 to MD4 may store data. Each of the memory dies MD1 to MD4 may include terminals MB. For example, the terminals MB may be micro bumps. Each of the terminals MB may include a data terminal for exchanging data with the memory dies MD1 to MD4 and may include a command/address terminal to perform an access to the memory dies MD1 to MD4.

The memory cell array 121 may exchange data with the base die BD through the data terminal among the terminals MB. The memory cell array 121 may receive command/address information (e.g., an internal address of the memory dies MD1 to MD4, at which an operation indicated by a command is to be performed) through the command/address terminal among the terminals MB. The memory cell array 121 may include through silicon vias TSV which connect the terminals MB to the base die BD in the vertical direction and penetrate or extend into the memory dies MD1 to MD4.

The base die BD may provide command/address information or data to the memory cell array 121. In some embodiments, the base die BD may include the row CA buffer 122, the column CA buffer 123, the CA decoder 124, the row decoder 125, the column decoder 126, or the input/output circuit 127 of FIG. 2. The base die BD may receive the row command/address signal R[9:0], the column command/address signal C[7:0], the control signal CTRL, the clocks CKs, or the data “DATA” to be stored, which are described with reference to FIG. 1, from the memory controller 115 of FIG. 1 and may output or receive the data “DATA” to or from the memory controller 115.

The structure on the semiconductor substrate of the memory device 120 described with reference to FIG. 3 is an example, and the present disclosure should not be limited thereto. It should be understood that a general structure of a semiconductor substrate of the HBM also belongs to the scope and spirit of the invention.

FIG. 4A is a diagram illustrating a row command truth table RCT according to some embodiments of the present disclosure, and FIG. 4B is a diagram illustrating a column command truth table CCT according to some embodiments of the present disclosure. FIGS. 4A and 4B may be collectively referred to as “FIG. 4”, and a command truth table may indicate the row command truth table RCT or the column command truth table CCT.

Referring to FIGS. 4A and 4B, a command corresponding to a value of each bit of a CA signal and clock timing, and an address of the memory cell array 121, at which the command is executed, are illustrated. The clock timing may be a rising (R) edge (or timing) or a falling (F) edge (or timing) of one clock among the clocks CKs of FIG. 2. In FIGS. 4A and 4B, shaded bit values among bit values of each CA signal may correspond to bits for identifying a command transferred through a CA signal. An example of a truth table of commands according to some embodiments of the present disclosure will be described with reference to FIGS. 1, 4A and/or 4B. In FIGS. 4A and 4B and the following drawings, “H” may indicate logical high, “L” may indicate logical low, and “V” may indicate an arbitrary valid signal (i.e., don't care). In FIGS. 4A and 4B, BA0, BA1, BA2, and BA3 may respectively indicate values of bits constituting a bank address (i.e., the bank address may be a 4-bit address, and BA3 may be a most significant bit (MSB) of the bank address). PC may indicate a selected pseudo channel, and SID may mean a stack ID. The PC and SID may be used to identify one of a plurality of banks together with the bank address BA0, BA1, BA2, and BA3. RA0 to RA14 may respectively indicate values of bits constituting a row address, and CA0 to CA4 may respectively indicate value of bits constituting a column address.

Referring to FIG. 4A, the memory device 120 may receive the row command/address signal R[9:0] corresponding to a precharge (PREpb) command at the rising (R) or falling (F) edge of the clock. The row command/address signal R[9:0] corresponding to the precharge command may provide a command through the 0-th row bit R[0] to the second row bit R[2] (R[2:0]=LLH) and may provide a location on the memory cell array 121 of FIG. 2, at which an operation is to be performed, through the remaining row bits R[3:9]. Likewise, for another example, an activate (ACT) operation may be performed through the rising (R), falling (F), and rising (R) timings of the clock and may be performed as the row command/address signal R[9:0] illustrated in FIG. 4A is received depending to the respective clock timings.

Referring to FIG. 4B, the memory device 120 may receive the column command/address signal C[7:0] corresponding to a read (Read) command at the rising (R) and falling (F) timings of the clock. For example, the column command/address signal C[7:0] corresponding to the read command may provide the read command through the 0-th column bit C[0] to the third column bit C[3] at the rising (R) edge of the clock and may provide a location, at which an operation is to be performed, through the remaining column bits C[4:7] and the whole column command/address signal C[7:0] received at the falling (F) edge. Like the read operation, a write operation may also be performed through the rising (R) and falling (F) timings of the clock and may be performed as the bits of the column command/address signal C[7:0] illustrated in FIG. 4B are sequentially received.

It should be understood that commands illustrated in FIGS. 4A and 4B and described through FIGS. 4A and 4B are provided as an example. The row command truth table RCT may include clock timings and bit values of the row command/address signal R[9:0] corresponding to any other operation(s) other than the above operations. In detail, the row command truth table RCT may include mapping between bit positions and clock timings of the row command/address signal R[9:0] and a command or a location where an operation indicated by the command is to be performed. Likewise, the column command truth table CCT may include clock timings and bit values of the column command/address signal C[7:0] corresponding to any other operation(s) other than the above operations. In detail, the column command truth table CCT may include mapping between bit positions and clock timings of the column command/address signal C[7:0] and a command and a location where an operation indicated by the command is to be performed. Based on various combinations of the bits of the row command/address signal R[9:0] or the column command/address signal C[7:0], the memory controller 115 may designate an operation of the memory device 120 or may control the memory device 120, and may provide a location (e.g., an address) on the memory cell array 121, at which an operation is to be performed.

For convenience of description, the CA signal may indicate the row command/address signal R[9:0] or the column command/address signal C[7:0], the buffered CA signal may indicate the buffered row command/address signal BR[9:0] or the buffered column command/address signal BC[7:0], and the CA buffer may indicate the row CA buffer 122 or the column CA buffer 123.

The memory device 120 may provide an idle mode or an activate mode. In the memory device 120, the transition from the idle mode to the activate mode may be made through an activating operation, and the transition from the activate mode to the idle mode may be made through the precharge operation. A first operation may indicate operations which the memory device 120 performs in the idle mode, and a second operation may indicate operations which the memory device 120 performs in the activate mode. For example, the first operation includes a mode register set (MRS) operation, an activating operation, etc. The second operation may include the read operation, the write operation, etc. A third operation may indicate an operation which is to be included in both the first operation and the second operation. The third operation may include a precharge (PREpb or PREab) operation or a power-down entry or power-down exit (PDE or PDX) operation, etc.

Referring to FIGS. 1, 2, 4A, and 4B together, the memory device 120 may receive CA signals and may generate buffered CA signals through corresponding CA buffers. In this case, a current consumption amount of the CA buffers may occupy a considerable portion of the whole current consumption amount of the memory device 120. The current consumption may cause the increase in heat generation of the memory device 120 and may cause the reduction of performance of the memory device 120. Also, the current consumption amount which exceeds the limitation of equipment testing the memory device 120 may hinder the smooth test of the memory device 120. Below, the memory device 120 capable of reducing the amount of current consumed in an operation and providing a smooth test will be described with reference to drawings.

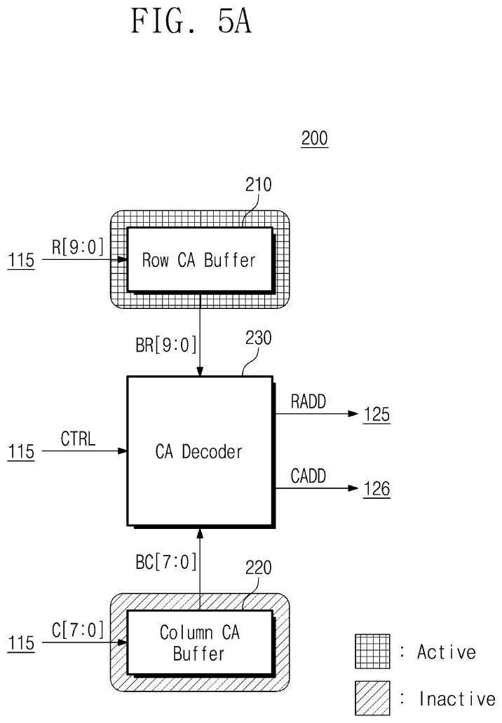

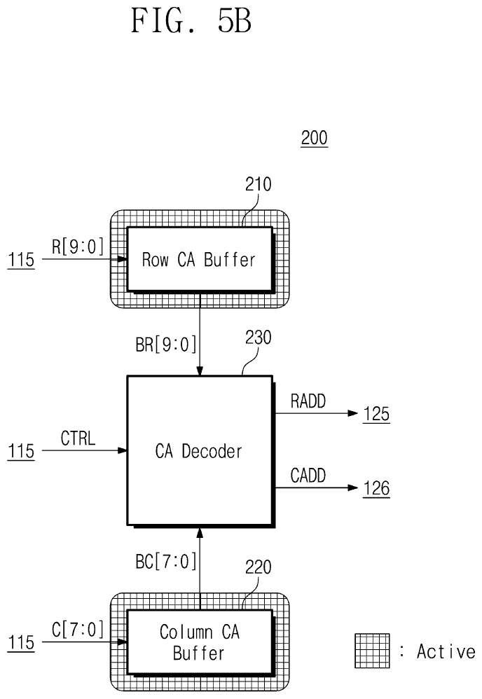

FIG. 5A is a block diagram illustrating a command/address (CA) unit 200 when the memory device 120 of FIG. 2 is in the idle mode, according to some embodiments of the present disclosure, and FIG. 5B is a block diagram illustrating the CA unit 200 when the memory device 120 of FIG. 2 is in the activate mode, according to some embodiments of the present disclosure. The CA unit 200 may correspond to a CA unit CA of FIG. 2. FIGS. 5A and 5B may be collectively referred to as “FIG. 5”. Referring to FIGS. 5A and 5B, the CA unit 200 may include a row CA buffer 210, a column CA buffer 220, and a CA decoder 230. A CA unit according to some embodiments of the present disclosure will be described with reference to FIGS. 5A and 5B.

The row CA buffer 210 may correspond to the row CA buffer 122 of FIG. 2. The row CA buffer 210 may receive the row command/address signal R[9:0] and may buffer the received row command/address signal R[9:0] to generate the buffered row command/address signal BR[9:0]. In some embodiments, the row CA buffer 210 may be activated regardless of the status of the memory device 120. For example, referring to FIGS. 5A and 5B, the row CA buffer 210 may be in an active state in both the idle mode and the activate mode. That is, an operating voltage may be applied to the row CA buffer 210, and a current may flow within the row CA buffer 210.

The column CA buffer 220 may correspond to the column CA buffer 123 of FIG. 2. The column CA buffer 220 may receive the column command/address signal C[7:0] and may buffer the received column command/address signal C[7:0] to generate the buffered column command/address signal BC[7:0]. In some embodiments, whether the column CA buffer 220 is activated may be determined depending on the memory status. For example, referring to FIG. 5A, the column CA buffer 220 may be an inactive state when the memory device 120 is in the idle mode. That is, an operating voltage is not applied to the column CA buffer 220, such that a current may not flow within the column CA buffer 220. Referring to FIG. 5B, the column CA buffer 220 may be in the active state when the memory device 120 is in the activate mode. When the column CA buffer 220 is in the inactive state, the column CA buffer 220 may fail to generate the buffered column command/address signal BC[7:0].

The CA decoder 230 may correspond to the CA decoder 124 of FIG. 2. The CA decoder 230 may receive buffered CA signals and may decode the received buffered CA signals. In this case, the CA decoder 230 may allow the memory device 120 to perform an operation indicated by a command corresponding to CA signals or may provide the row address RADD and the column address CADD to the row decoder 125 and the column decoder 126, respectively, such that a location on the memory cell array 121 indicated by the CA signals is selected.

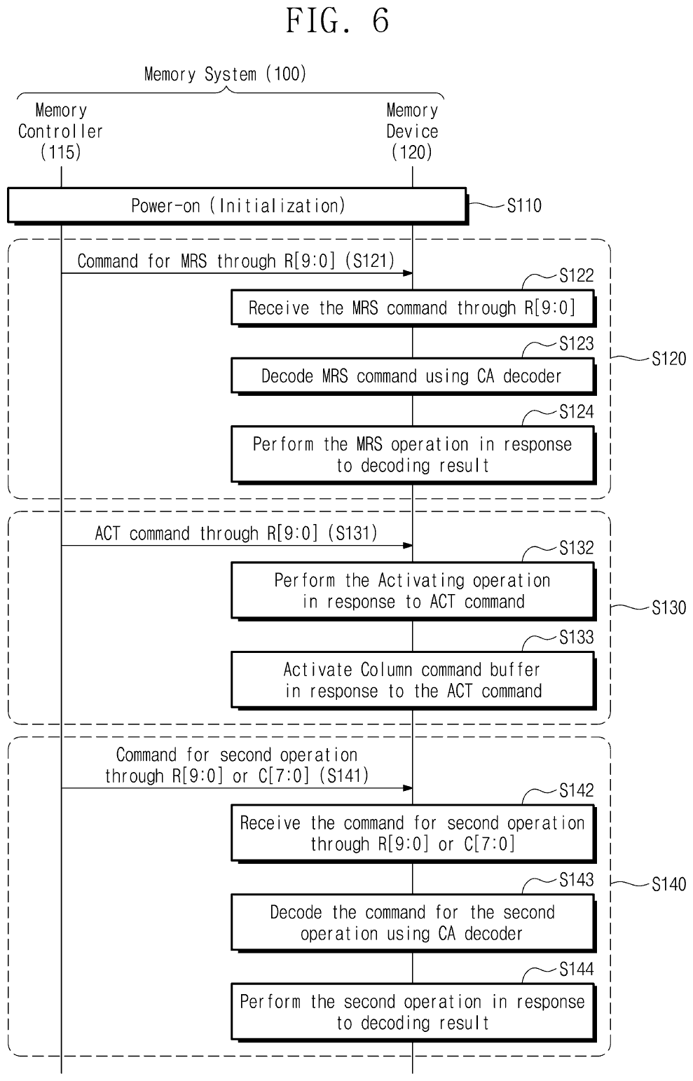

FIG. 6 is a flowchart illustrating an operation sequence of the memory system 100 of FIG. 1, according to some embodiments of the present disclosure. An operation sequence of the memory system 100 according to some embodiments of the present disclosure will be described with reference to FIGS. 1, 5A, 5B, and 6.

In operation S110, the memory system 100 may be powered on. In some embodiments, after the memory device 120 is powered on, the memory device 120 may enter an idle state depending on a given sequence. For example, after the memory device 120 is powered on, the memory device 120 may enter the idle mode through a reset process. In some embodiments, when the memory device 120 enters the idle mode, the memory device 120 may set the CA buffer to the active state. For example, as illustrated in FIG. 5A, the memory device 120 may allow the row CA buffer 210 to be in the active state and may maintain the column CA buffer 220 in the inactive state.

In operation S120, the memory device 120 may perform an MRS operation in the idle mode. Operation S120 may include operations S121, S122, S123, and S124. In some embodiments, the memory device 120 may include the CA unit 200 set as illustrated through FIG. 5A in the idle mode. FIG. 6 is described based on the case where the memory device 120 performs the MRS operation, but this is provided as an example. It should be understood that the first operation of the memory device 120 is capable of being performed depending on the sequence of operation S120.

In operation S121, the memory controller 115 may transmit the row command/address signal R[9:0] corresponding to an MRS command to the memory device 120. Likewise, the memory controller 115 may transmit the row command/address signal R[9:0] corresponding to a command indicating the first operation different from the MRS operation to the memory device 120 in the same method.

In operation S122, the memory device 120 may receive the row command/address signal R[9:0] corresponding to the MRS command. Likewise, the memory device 120 may receive the row command/address signal R[9:0] corresponding to a command indicating the first operation other than the MRS operation in the same method.

In operation S123, the memory device 120 may decode the row command/address signal R[9:0] corresponding to the MRS command. In some embodiments, the memory device 120 may decode the row command/address signal R[9:0] corresponding to the MRS command through the CA decoder 230. For example, the memory device 120 may decode the MRS command by generating the buffered row command/address signal BR[9:0] corresponding to the MRS command through the row CA buffer 210 and decoding the buffered row command/address signal BR[9:0] through the CA decoder 230. Likewise, the memory device 120 may decode the row command/address signal R[9:0] corresponding to the command indicating the first operation other than the MRS operation in the same method.

In operation S124, the memory device 120 may perform the MRS operation based on the decoding result. Likewise, the memory device 120 may perform the first operation other than the MRS operation in the same method.

The memory device 120 may perform the first operation including the MRS operation through operation S120. In operation S120, the memory device 120 may perform the first operation while the column CA buffer 220 in the inactive state, and thus, the amount of current unnecessarily consumed by the column CA buffer 220 may be reduced. Compared to a memory device where the MRS command is received by the column command/address signal C[7:0], the memory device 120 according to some embodiments of the present disclosure may reduce the current consumption of the CA buffer. The memory system 100 may repeat operation S120 or may proceed to operation S130 after operation S120.

In operation S130, the memory device 120 may be activated. Operation S130 may include operation S131 and operation S132. In operation S130, the memory device 120 may be activated and may enter the activate mode.

In operation S131, the memory controllers 115 may transmit the activate (ACT) command to the memory device 120. In some embodiments, the memory controller 115 may transmit the row command/address signal R[9:0] corresponding to the activate command to the memory device 120. For example, the memory controller 115 may transmit the row command/address signal R[9:0] corresponding to the activate (ACT) command described with reference to FIG. 4A during 1.5 cycles of the clock.

In operation S132, the memory device 120 may perform the activating operation in response to the activate command. For example, the memory device 120 may perform the activating operation by decoding the row command/address signal R[9:0] corresponding to the activate command through the CA decoder 230. In operation S133, the memory device 120 may allow the column CA buffer 220 to enter the active state. For example, in response to the activate command, the memory device 120 may allow the column CA buffer 220 to enter the active state. Operation S132 and operation S133 are disclosed sequentially for convenience of description, and the present disclosure is not limited thereto. For example, it should be understood that operation S132 and operation S133 are capable of being performed at the same time or the sequence of operation S132 and operation S133 may be changed, in some embodiments.

After operation S130 ends, the memory device 120 may set all the CA buffers to the active state. That is, the CA unit 200 of the memory device 120 may be the same as the CA unit 200 described with reference to FIG. 5B. The memory system 100 may proceed to operation S140.

In operation S140, the memory device 120 may be in the activate mode and may perform the second operation. Operation S140 may include operations S141, S142, S143, and S144. In some embodiments, the memory device 120 may include the CA unit 200 set as illustrated through FIG. 5B in operation S140.

In operation S141, the memory controller 115 may transmit commands indicating the second operation to the memory device 120. In some embodiments, the memory controller 115 may transmit the command indicating the second operation to the memory device 120 through the row command/address signal R[9:0] or the column command/address signal C[7:0]. For example, the memory controller 115 may transmit the column command/address signal C[7:0] corresponding to the read command to the memory device 120 and may transmit the row command/address signal R[9:0] corresponding to the precharge command to the memory device 120.

In operation S142, the memory device 120 may receive the command indicating the second operation. For example, the memory device 120 may receive the row command/address signal R[9:0] or the column command/address signal C[7:0] corresponding to the command indicating the second operation from the memory controller 115.

In operation S143, the memory device 120 may decode the command indicating the second operation. In some embodiments, the memory device 120 may decode the command indicating the second operation through the CA decoder 230. For example, the memory device 120 may decode the command indicating the second operation by generating buffered CA signals from CA signals corresponding to the command indicating the second operation through the CA buffer and decoding the buffered CA signals through the CA decoder 230.

In operation S144, the memory device 120 may perform the second operation based on the decoding result. For example, the memory device 120 may perform the read operation or the write operation corresponding to the decoding result.

After operation S140 ends, the memory device 120 may again perform operation S140.In some embodiments, after operation S140 ends, the memory device 120 may proceed to operation S120 while entering the idle mode. In this case, the CA unit 200 of the memory device 120 may switch from the state of the CA unit 200 of FIG. 5B to the state of the CA unit 200 of FIG. 5A. In some embodiments, after the memory device 120 performs the precharge operation in operation S140, the memory device 120 may proceed to operation S120 (i.e., may enter the idle mode) and may then again perform the first operation including the MRS operation.

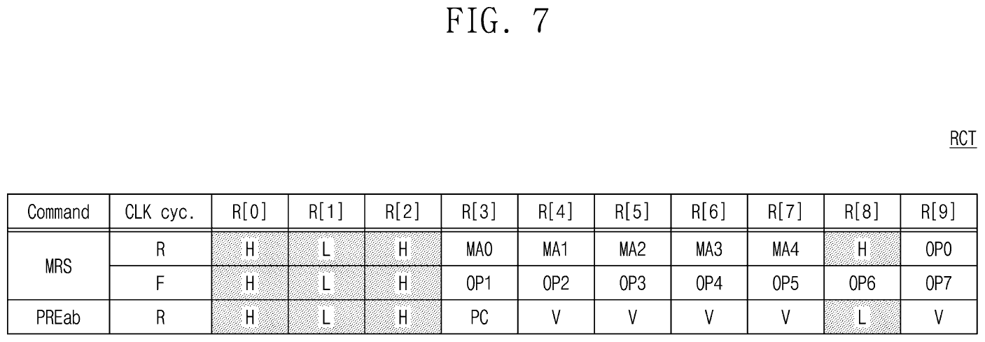

FIG. 7 is a diagram illustrating the row command truth table RCT of a memory system, according to some embodiments of the present disclosure. some embodiments of the row command/address signal R[9:0] indicating the MRS operation and the row command/address signal R[9:0] of the first operation will be described with reference to FIGS. 6 and 7.

Referring to FIG. 7, the row command truth table RCT of the MRS operation and a precharge all (PREab) operation is illustrated. In FIG. 7 and the following, MA0, MA1, MA2, MA3, and MA4 may indicate bits (e.g., MA4 being an MSB of an address value of a mode register) corresponding to an address value of a mode register to be set, and OP0, OP1, OP2, OP3, OP4, OP5, OP6, and OP7 may indicate values to be set in respective mode registers.

The MRS operation may be performed through the rising (R) and falling (F) timings of the clock. The row command/address signal R[9:0] corresponding to the MRS command may indicate the MRS operation through the 0-th to second row bits R[2:0] and the eighth row bit R[8] at the rising (R) timing of the clock and may indicate the MRS operation through the 0-th to second row bits R[2:0] at the falling (F) timing of the clock (R[2:0]=HLH). The row command/address signal R[9:0] corresponding to the MRS command may provide the mode register address MAO, MA1, MA2, MA3, and MA4 to be set and the values OP0, OP1, OP2, OP3, OP4, OP5, OP6, and OP7 to be set, through the remaining bits other than the above bits, at the rising (R) and falling (F) timings of the clock.

The row command/address signal R[9:0] described with reference to FIG. 7 is provided as an example, and the present disclosure is not limited to the truth table illustrated in FIG. 7. It should be understood that an arbitrary row command truth table RCT of the row command/address signal R[9:0] allowing the memory system 100 to perform the operation(s) described with reference to FIGS. 5 and 6 belongs to the scope and spirit of the invention. In some embodiments, the truth table of the row command/address signal R[9:0] may include clock timings and bit values of the row command/address signal R[9:0] corresponding to the command indicating the first operation.

An embodiment in which the CA unit 200 included in the memory device 120 is set as illustrated in FIG. 5B in the activate mode is described with reference to FIGS. 5 to 7, but the present disclosure is not limited thereto. The memory device 120 may include the CA unit 200 which is set as illustrated in FIG. 5A in the idle mode. In the activate mode, the memory device 120 may include the row CA buffer 210 of the inactive state and the column CA buffer 220 of the activate mode. In this case, in operation S130, after the activating operation, the memory system 100 may allow the row CA buffer 210 to enter the inactive state while changing the state of the column CA buffer 220 to the active state. Also, the truth table of the column command/address signal C[7:0] described with reference to FIG. 4B may further include a clock timing of each of commands indicating the third operation and bit values or information of the column command/address signal C[7:0] indicating the third operation. That is, in the memory system 100, only the column CA buffer 220 may be in the active state in operation S140. Afterwards, when the memory device 120 enters the idle mode (i.e., when the memory device 120 returns to operation S120), the memory device 120 may change the state of the row CA buffer 210 to the active state and may change the state of the column CA buffer 220 to the inactive state. Accordingly, compared to the embodiments described with reference to FIG. 6, the memory device 120 may further reduce the amount of current consumption of the CA buffer during all the operations.

The memory system 100 described with reference to FIGS. 5 to 7 may remove or reduce the amount of current consumption of the column CA buffer 220 in the idle mode, by allowing the column CA buffer 220 to remain in the inactive state in the idle mode. This may mean that a current consumption amount is reduced during all the operations of the memory system 100. In other words, this may mean that the amount of heat generation is reduced during all the operations of the memory system 100. Also, in the memory system 100, even though the number of memory controllers 115 and the number of channels of the memory device 120 increase, the increment of current may be reduced during the operation of the memory system 100. As another example, the memory system 100 may allow the test of the memory system 100 to be performed more efficiently through the operation(s) described with reference to FIGS. 5 to 7, and thus, the performance of operation of the memory system 100 may be improved.

Below, referring to FIG. 1 together for convenience of description, the memory device 120 may include a first mode and a second mode. In the case of the first mode, the memory device 120 may include the CA unit 200 set as illustrated in FIG. 5A in the idle mode and may include the CA unit 200 set as illustrated in FIG. 5B in the activate mode. In the case of the second mode, the memory device 120 may include the CA unit 200 set as illustrated in FIG. 5B, in both the idle mode and the activate mode. In the case of the first mode, the memory device 120 may receive the commands indicating the first operation through the row command/address signal R[9:0]. For example, the memory device 120 may receive the command indicating the MRS operation through the row command/address signal R[9:0] in the first mode. In the case of the second mode, the memory device 120 may receive the commands indicating the first operation through the row command/address signal R[9:0] or the column command/address signal C[7:0]. For example, the memory device 120 may receive the command indicating the MRS operation through the column command/address signal C[7:0] in the second mode. In some embodiments, the memory device 120 may switch between the first mode and the second mode under control of the memory controller 115. In some embodiments, the memory device 120 may switch between the first mode and the second mode in response to the control signal CTRL of the memory controller 115. In some embodiments, the memory device 120 may switch between the first mode and the second mode, based on the MRS operation.

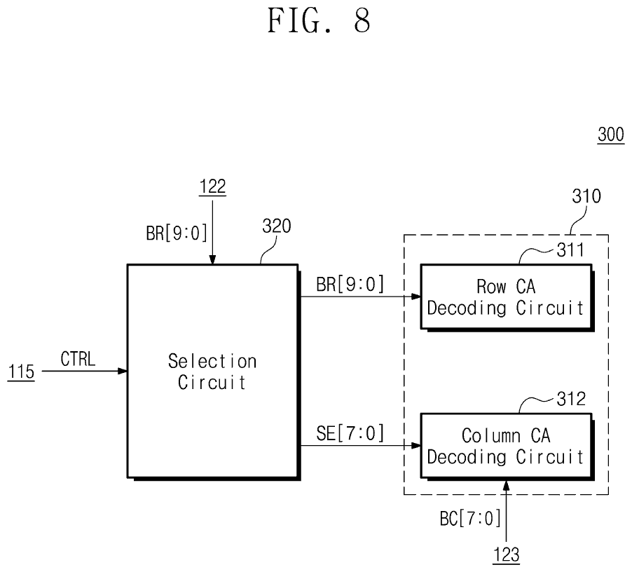

FIG. 8 is a block diagram illustrating a CA decoder according to some embodiments of the present disclosure. A CA decoder 300 may correspond to the CA decoder 124 of FIG. 2. Referring to FIG. 8, the CA decoder 300 may include a decoding circuit 310 and a selection circuit 320. The CA decoder 300 according to some embodiments of the present disclosure will be described with reference to FIGS. 2 and 8.

The decoding circuit 310 may decode a buffered CA signal. The decoding circuit 310 may include a row command/address (CA) decoding circuit 311 and a column command/address (CA) decoding circuit 312. The row CA decoding circuit 311 may decode the buffered row command/address signal BR[9:0] received from the row CA buffer 122 and may allow the memory device 120 to perform an operation indicated by a command corresponding to the row command/address signal R[9:0]. The column CA decoding circuit 312 may decode the buffered column command/address signal BC[7:0] received from the column CA buffer 123 and may allow the memory device 120 to perform an operation indicated by a command corresponding to the column command/address signal C[7:0].

In some embodiments, the column CA decoding circuit 312 may receive and decode a selection signal SE[7:0] from the selection circuit 320. For example, the column CA decoding circuit 312 may decode the selection signal SE[7:0] and may allow the memory device 120 to perform an operation corresponding to a command which is used to generate the selection signal SE[7:0]. The selection signal SE[7:0] will be described in detail through the selection circuit 320.

The selection circuit 320 may selectively transfer the buffered row command/address signal BR[9:0] from the row CA buffer 122 to the row CA decoding circuit 311 or the column CA decoding circuit 312. In some embodiments, the selection circuit 320 may operate in response to the control signal CTRL of the memory controller 115 of FIG. 1. For example, in response to the control signal CTRL, the selection circuit 320 may transfer the received buffered row command/address signal BR[9:0] to the row CA decoding circuit 311 or the column CA decoding circuit 312.

In some embodiments, the selection circuit 320 may generate the selection signal SE[7:0] whose bit length is the same as that of the column command/address signal C[7:0], based on the buffered row command/address signal BR[9:0] so as to be provided to the column CA decoding circuit 312. For example, the selection circuit 320 may generate the remaining bits of the buffered row command/address signal BR[9:0] other than the ninth bit BR[9] and the eighth bit BR[8] as the selection signal SE[7:0] and may provide the generated selection signal SE[7:0] to the column CA decoding circuit 312. In detail, to allow the memory device 120 to perform the MRS operation, the selection circuit 320 may generate the selection signal SE[7:0] based on the buffered row command/address signal BR[9:0] indicating the MRS operation, so as to be provided to the column CA decoding circuit 312.

The generation of the selection signal SE[7:0] from the buffered row command/address signal BR[9:0] is provided as an example, and the present disclosure should not be limited thereto. For another example, the selection circuit 320 may generate the selection signal SE[7:0] by excluding the eight bit BR[8] and the first bit BR[1] of the buffered row command/address signal BR[9:0].

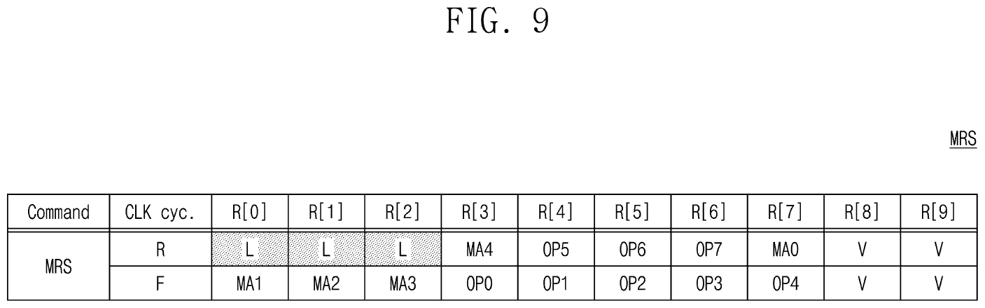

FIG. 9 is a diagram illustrating an example of a truth table of a row command corresponding to a first operation, according to some embodiments of the present disclosure. Referring to FIG. 9, a truth table MRS of the row command/address signal R[9:0] indicating the MRS operation of the first operation is illustrated. In FIG. 9, shaded bit values may mean values of bits specifying a kind of a command. According to some embodiments, a command corresponding to an operation of the memory device 120 including the CA decoder 300 of FIG. 8 will be described with reference to FIG. 9.

Referring to FIG. 9, the MRS operation may be performed through the rising (R) and falling (F) edges of the clock. The 0-th to second row bits R[2:0] of the row command/address signal R[9:0] indicating the MRS operation may indicate the MRS operation at the rising (R) edge of the clock (R[2:0]=LLL). The row command/address signal R[9:0] indicating the MRS operation may provide an address of a mode register to be set and values to be set, through the 0-th to seventh row bits R[7:0] at the falling (F) edge of the clock and the third to seventh row bits R[7:3] at the rising (R) edge of the clock.

Referring to FIG. 8 together, the MRS command of FIG. 9 may be provided to the memory device 120 by using the row command/address signal R[9:0]. The MRS command may be provided to the selection circuit 320 through the row CA buffer 210 in the form of the buffered row command/address signal BR[9:0] so as to be generated as the selection signal SE[7:0] by the selection circuit 320 and the control signal CTRL, and the selection signal SE[7:0] thus generated may be provided to the column CA decoding circuit 312. In some embodiments, in FIG. 9, the remaining bits of the MRS command other than bits of “V” may be the same as those of the column command/address signal C[7:0] corresponding to the command indicating the MRS operation. For example, the 0-th to seventh row bits R[7:0] of the row command/address signal R[9:0] corresponding to the MRS operation may be the same as those of the column command/address signal C[7:0] corresponding to the MRS operation.

The row command/address signal R[9:0] of FIG. 9 corresponding to the MRS operation is provided as an example, and the present disclosure is not limited thereto. It should be understood that an arbitrary truth table MRS for the MRS command, in which the remaining bits other than the bits of “V” are able to be the same as those of the column command/address signal C[7:0] corresponding to the MRS operation, belongs to the scope and spirit of the invention. Also, it should be understood that the above embodiments are able to be applied to the first operation other than the MRS operation.

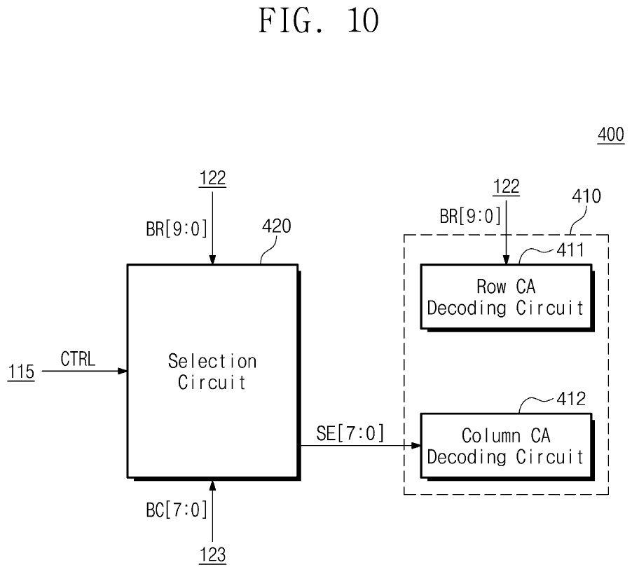

FIG. 10 is a block diagram illustrating a CA decoder 400 in detail, according to some embodiments of the present disclosure. The CA decoder 400 may correspond to the CA decoder 124 of FIG. 2. Referring to FIG. 10, the CA decoder 400 may include a decoding circuit 410 and a selection circuit 420. The CA decoder 400 according to some embodiments of the present disclosure will be described in tail with reference to FIGS. 2 and 10.

The decoding circuit 410 may decode commands to allow an operation indicated by a command to be performed by the memory device 120 or may decode the commands to designate a location of the memory cell array 121, at which the operation indicated by the command is to be performed.

The decoding circuit 410 may include a row CA decoding circuit 411 and a column CA decoding circuit 412. The row CA decoding circuit 411 may receive the buffered row command/address signal BR[9:0] corresponding to a command from the row CA buffer 122 and may decode the received buffered row command/address signal BR[9:0] to allow the memory device 120 to perform an operation indicated by the command.

The column CA decoding circuit 412 may receive the selection signal SE[7:0] from the selection circuit 420 and may decode the received selection signal SE[7:0] to allow the memory device 120 to perform an operation indicated by a command corresponding to the selection signal SE[7:0]. In some embodiments, the selection signal SE[7:0] may be generated based on one of the buffered column command/address signal BC[7:0] and the buffered row command/address signal BR[9:0]. The selection signal SE[7:0] will be described in detail together with the selection circuit 420.

The selection circuit 420 may generate the selection signal SE[7:0], based on one of the buffered row command/address signal BR[9:0] and the buffered column command/address signal BC[7:0]. In some embodiments, the selection circuit 420 may operate in response to the control signal CTRL received from the memory controller 115 of FIG. 1. For example, the selection circuit 420 may generate the selection signal SE[7:0] based on one of the buffered row command/address signal BR[9:0] and the buffered column command/address signal BC[7:0] in response to the control signal CTRL and may provide the generated selection signal SE[7:0] to the column CA decoding circuit 412.

In some embodiments, the selection circuit 420 may generate the selection signal SE[7:0] whose bit length is the same as that of the buffered column command/address signal BC[7:0], based on the buffered row command/address signal BR[9:0] so as to be provided to the column CA decoding circuit 412. For example, the selection circuit 420 may generate the remaining bits of the buffered row command/address signal BR[9:0] other than the eighth and ninth buffered row bits BR[9:8] as the selection signal SE[7:0] and may provide the generated selection signal SE[7:0] to the column CA decoding circuit 412. In detail, the selection circuit 420 may receive the buffered row command/address signal BR[9:0] corresponding to the MRS command of FIG. 9 and may generate the selection signal SE[7:0] corresponding to the MRS command so as to be provided to the column CA decoding circuit 412.

The change from the buffered row command/address signal BR[9:0] to the selection signal SE[7:0] is provided as an example, and the present disclosure should not be limited thereto. For another example, other bits of BR[9:0] may be excluded, such as the selection circuit 320 may generate the selection signal SE[7:0] by excluding the seventh bit BR[7] and the fourth bit BR[4] of the buffered row command/address signal BR[9:0].

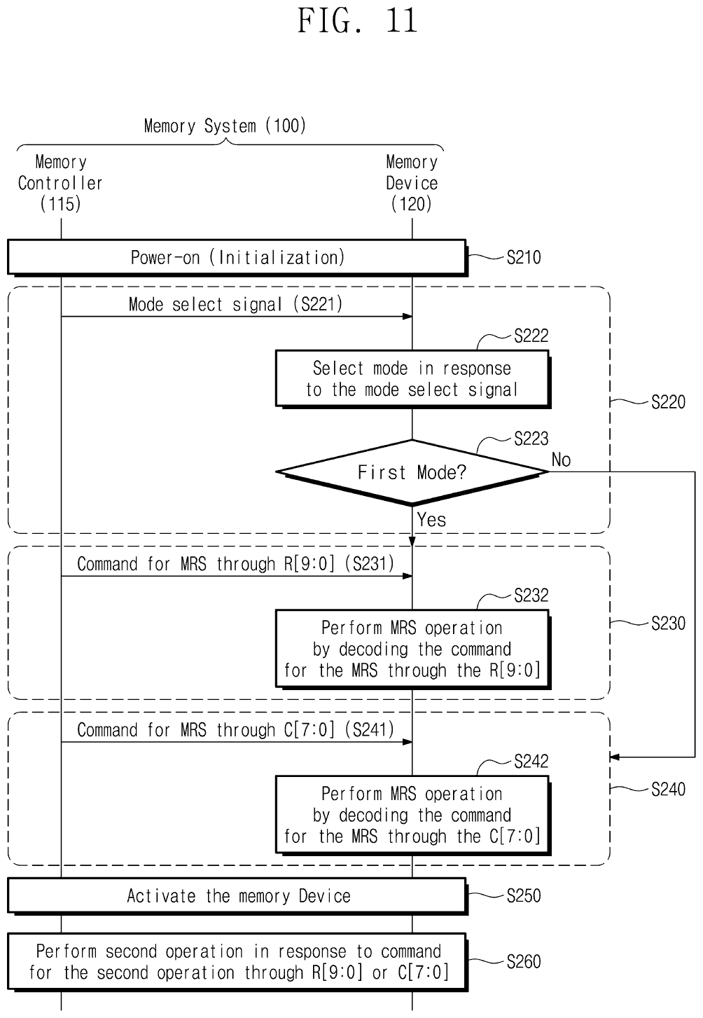

FIG. 11 is a flowchart illustrating an operation sequence of the memory system 100 including the memory device 120 of FIG. 2 including the CA decoder 300 of FIG. 8 or the CA decoder 400 of FIG. 10, according to some embodiments of the present disclosure. An operation sequence of the memory system 100 according to some embodiments of the present disclosure will be described with reference to FIGS. 1, 5, and 8 to 11.

In operation S210, the memory system 100 may be powered on. Like operation S110 of FIG. 6, the memory device 120 may enter the idle mode depending on a given sequence. In some embodiments, when the memory device 120 enters the idle mode, the memory device 120 may set the CA buffer to the active state. For example, as illustrated in FIG. 5A, the memory device 120 may set only the row CA buffer 210 to the active state.

In operation S220, the memory system 100 may select one of the first mode and the second mode of the memory device 120. Operation S220 may include operations S221, S222, and operation S223.

In operation S221, the memory controller 115 may transmit a mode select signal to the memory device 120. In some embodiments, the mode select signal may be included in the control signal CTRL. In some embodiments, the memory controller 115 may transmit the mode select signal to the memory device 120 through the CA decoder 230. For example, the memory controller 115 may transmit the control signal CTRL including the mode select signals to the CA decoder 230.

In operation S222, the memory device 120 may select an operating mode (e.g., the first mode or the second mode) in response to the mode select signal. In some embodiments, the memory device 120 may determine the active state of the CA buffer of the memory device 120 in response to the mode select signal. For example, when the memory device 120 receives the mode select signal corresponding to the first mode, the memory device 120 may enter the first mode.

The memory device 120 may differently set the active state of the CA buffer depending on the first mode or the second mode. For example, when the memory device 120 enters the first mode, like the CA unit 200 of FIG. 5A, the memory device 120 may allow the row CA buffer 210 to be set to the active state and may allow the column CA buffer 220 to be set to the inactive state. For another example, when the memory device 120 enters the second mode, like the CA unit 200 of FIG. 5B, the memory device 120 may allow the row CA buffer 210 and the column CA buffer 220 to be set to the active state.

In operation S223, the memory system 100 may differently perform the procedure depending on whether the memory device 120 enters the first mode or the second mode. When the memory device 120 enters the first mode, the memory system 100 may perform operation S230, and when the memory device 120 enters the second mode, the memory system 100 may perform operation S240.

In operation S230, the memory device 120 may perform the MRS operation in the first mode. Operation S230 may include operation S231 and operation S232. Operation S230 will be described based on the MRS operation, but it should be understood that the first operation of the memory device 120 is the same as the MRS operation or is able to be performed in a method similar to that of the MRS operation.

In operation S231, the memory controller 115 may transmit the row command/address signal R[9:0] corresponding to an MRS command to the memory device 120. Likewise, the memory controller 115 may transmit the row command/address signal R[9:0] indicating the first operation other than the MRS operation to the memory device 120.

In operation S232, the memory device 120 may perform the MRS operation by decoding the row command/address signal R[9:0] corresponding to the MRS operation. For example, the memory device 120 may perform the MRS operation by decoding the row command/address signal R[9:0] corresponding to the MRS command through the row CA buffer 210 and the CA decoder 230. Likewise, the memory device 120 may perform the first operation other than the MRS operation in a method the same as or similar to the above method.

In some embodiments, the memory device 120 may decode the MRS command received through the row command/address signal R[9:0] by using the CA decoder 300 or 400 described with reference to FIG. 8 or 10 and may allow the memory device 120 to perform the MRS operation. In some embodiments, the memory device 120 may perform the MRS operation in a method the same as or similar to the method described with reference to operations S122, S123, and S124 of FIG. 6. After operation S230, the memory system 100 may again repeat operation S230 or may proceed to operation S250.

In operation S240, the memory device 120 may perform the MRS operation in the second mode. In some embodiments, the memory device 120 may receive the column command/address signal C[7:0] corresponding to the MRS operation and may perform the MRS operation. In this case, as described above, both the row CA buffer 210 and the column CA buffer 220 of the memory device 120 may be set to the active state.

In the case of performing the first operation other than the MRS operation, the memory device 120 may receive the row command/address signal R[9:0] or the column command/address signal C[7:0] indicating the first operation other than the MRS operation and may perform the first operation other than the MRS operation. When the memory device 120 performs the first operation indicated by the row command/address signal R[9:0], the memory device 120 may perform the first operation indicated by the row command/address signal R[9:0] in a method the same as or similar to the method described through operation S230. Operation S240 may include operation S241 and operation S242.

In operation S241, the memory controller 115 may transmit the column command/address signal R[7:0] corresponding to the MRS operation to the memory device 120. Likewise, the memory controller 115 may transmit the column command/address signal C[7:0] indicating the first operation to the memory device 120.

In operation S242, the memory device 120 may perform the MRS operation, based on decoding the column command/address signal C[7:0] corresponding to the MRS operation. For example, the memory device 120 may perform the MRS operation by buffering the column command/address signal C[7:0] received through the column CA buffer 220 and decoding the received column command/address signal C[7:0] through the CA decoder 230. Likewise, the memory device 120 may perform the first operation other than the MRS operation, which the column command/address signal C[7:0] indicates, in a method the same as or similar to the above method. After operation S240, the memory system 100 may again repeat operation S240 or may proceed to operation S250.

In operation S250, the memory device 120 may be activated. The memory device 120 may be activated and may enter the activate mode. The activating operation of the memory device 120 may be performed to be the same as or similar to that in operation S130 of FIG. 6. In some embodiments, when the memory device 120 is powered on from operation S230, the memory device 120 may allow the column CA buffer 220 to be set to the active state. After operation S250 ends, the memory device 120 may set all the CA buffers to the active state. That is, the CA unit 200 of the memory device 120 may be the same as the CA unit 200 described with reference to FIG. 5B. The memory system 100 may proceed to operation S260.

In operation S260, the memory device 120 may be in the activate mode and may perform the second operation in response to the row command/address signal R[9:0] or the column command/address signal C[7:0]. The memory system 100 may perform the second operation in a manner the same as or similar to that in operation S140 of FIG. 6. After operation S260 ends, the memory system 100 may again repeat operation S260 or may return to the idle mode. When the memory device 120 is in the first mode, the memory system 100 may return to operation S230, and when the memory device 120 is in the second mode, the memory system 100 may return to operation S240.

Embodiments in which the CA unit 200 included in the memory device 120 is set as illustrated in FIG. 5B in the activate mode is described with reference to FIGS. 5A, 5B, 6, 7, 8, 9, 10, and 11, but the present disclosure is not limited thereto. In the idle mode, the memory device 120 may include the CA unit 200 which is set as illustrated in FIG. 5A. In the activate mode, the memory device 120 may include the row CA buffer 210 of the inactive state and the column CA buffer 220 of the activate mode. In this case, in operation S250, after the activating operation, the memory system 100 may allow the row CA buffer 210 to enter the inactive state while changing the state of the column CA buffer 220 to the active state. Also, the truth table of the column command/address signal C[7:0] described with reference to FIG. 4B may further include a clock timing of each of commands indicating the third operation and bit values or information of the column command/address signal C[7:0] indicating the third operation. That is, in the memory system 100, only the column CA buffer 220 may be in the active state in operation S260. Afterwards, when the memory device 120 returns to the idle mode (i.e., when the memory device 120 returns to operation S230 or operation S240), the memory device 120 may change the state of the CA buffer to the active state so as to correspond to each of the first mode and the second mode. Accordingly, compared to the embodiment described with reference to FIG. 11, the memory device 120 may further reduce the amount of current consumption of the CA buffer during all the operations.

In some embodiments, the operating mode may be changed in a time period where the memory device 120 proceeds to operation S250 from operation S230 or operation S240. For example, after the memory device 120 completes operation S230 in the first mode, the memory device 120 may enter the second mode before proceeding to operation S250. In detail, after the memory device 120 completes operation S230, the memory controller 115 may transmit the control signal CTRL to the memory device 120 such that the memory device 120 enters the second mode, and the memory device 120 may then proceed to operation S250 in the second mode. Likewise, in some embodiments, after operation S250, the memory device 120 may enter the first mode or the second mode and may then proceed to operation S230 or operation S240.

The operation method of the memory system 100 according to some embodiments of the present disclosure is described with reference to FIGS. 1, 2, 3, 4A, 4B, 5A, 5B, 8, 9, 10, and 11. According to the above embodiments, the memory system 100 may select one of the first mode or the second mode and may operate in the selected mode. When the memory system 100 is in the first mode, like the memory system 100 described with reference to FIG. 6, the column CA buffer 220 may be set to the inactive state, and thus, unnecessary current consumption may be removed or reduced.

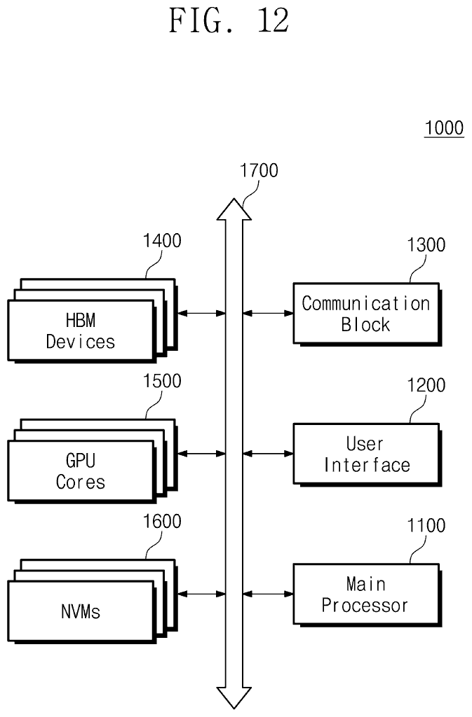

FIG. 12 is a block diagram illustrating an electronic system according to some embodiments of the present disclosure. Referring to FIG. 12, an electronic system 1000 may include a main processor 1100, a user interface 1200, a communication block 1300, HBM devices 1400, graphics processing unit (GPU) cores 1500, and non-volatile memories (NVMs) 1600. For example, the electronic system 1000 may be one of electronic devices such as a desktop computer, a laptop computer, a tablet computer, a smartphone, a wearable device, a video game console, a workstation, and a server or may be one of processing units such as a neural processing unit (NPU) and a graphics processing unit (GPU).

The main processor 1100 may control all operations of the electronic system 1000. The main processor 1100 may perform various kinds of arithmetic operations and/or logic operations. To this end, the main processor 1100 may include a special-purpose circuit (e.g., a field programmable gate array (FPGA) or an application specific integrated circuits (ASICs)). For example, the main processor 1100 may include one or more processor cores and may be implemented with a general-purpose processor, a special-purpose processor, or an application processor. In some embodiments, the main processor 1100 may include a memory controller (e.g., the memory controller 115 of FIG. 1) described with reference to FIGS. 1, 2, 3, 4A, 4B, 5A, 5B, 6, 7, 8, 9, 10, and 11, to control the HBM devices 1400.

The communication block 1300 may communicate with an external device/system of the electronic system 1000. For example, the communication block 1300 may support at least one of various wireless communication protocols such as long term evolution (LTE), worldwide interoperability for microwave access (WIMAX), global system for mobile communications (GSM), code division multiple access (CDMA), Bluetooth, near field communication (NFC), wireless fidelity (Wi-Fi) and radio frequency identification (RFID) and/or at least one of various wired communication protocols such as transfer control protocol/internet protocol (TCP/IP), a universal serial bus (USB), and/or Firewire.

The user interface 1200 may arbitrate the communication between the user and the electronic system 1000. For example, the user interface 1200 may include an input interface such as a keyboard, a mouse, a keypad, a button, a touch panel, a touch screen, a touch pad, a touch ball, a camera, a microphone, a gyroscope sensor, or a vibration sensor. For example, the user interface 1200 may include an output interface such as a liquid crystal display (LCD) device, a light emitting diode (LED) display device, an organic LED (OLED) display device, an active matrix OLED (AMOLED) display device, a speaker, or a motor.

The HBM devices 1400 may store data or instructions necessary for the operation of the electronic system 1000. For example, the HBM devices 1400 may store data or instructions necessary for an operation of the main processor 1100, the communication block 1300, or the GPU cores 1500 of the electronic system 1000 and may provide the data or instructions to respective devices in response to a request. Each of the HBM devices 1400 may be the memory device 120 included in the memory system 100 described with reference to FIGS. 1, 2, 3, 4A, 4B, 5A, 5B, 6, 7, 8, 9, 10, and 11 or may include the memory device 120.

The GPU cores 1500 may perform various operations at high speed. In some embodiments, the GPU cores 1500 may perform graphics processing, machine learning and inference, or an artificial intelligence inference operation. The GPU cores 1500 may perform operations in parallel. In some embodiments, the GPU cores 1500 may receive data or an instruction necessary for an operation from the HBM devices 1400 and may again transmit a processing result to the HBM devices 1400. In some embodiments, the GPU cores 1500 may include a memory controller (e.g., the memory controller 115 of FIG. 1) described with reference to FIGS. 1, 2, 3, 4A, 4B, 5A, 5B, 6, 7, 8, 9, 10, and 11, to control the HBM devices 1400.

The NVMs 1600 may store data necessary for the operation of the electronic system 1000 or data generated as a result of the operation. In some embodiments, the NVMs 1600 may store data generated through the operation of the main processor 1100 or the GPU cores 1500. In some embodiments, the NVMs 1600 may store data present in the HBM devices 1400 or may provide the stored data to the HBM devices 1400. The NVMs 1600 may be controlled by the main processor 1100.

A bus 1700 may provide a communication path between the components of the electronic system 1000. The components of the electronic system 1000 may exchange data with each other based on the bus format of the bus 1700. For example, the bus format may include at least one or more of various interface protocols such as USB, small computer system interface (SCSI), peripheral component interconnect express (PCIe), mobile PCle (M-PCIe), advanced technology attachment (ATA), parallel ATA (PATA), serial ATA (SATA), serial attached SCSI (SAS), integrated drive electronics (IDE), enhanced IDE (EIDE), non-volatile memory express (NVMe), and/or universal flash storage (UFS).

According to the electronic system 1000 of FIG. 12, a current consumption amount of a memory device may be reduced by the HBM devices 1400 according to some embodiments of the present disclosure. In addition, the electronic system 1000 may reduce a power consumption amount and the amount of heat generation in addition to the reduced current consumption amount and may allow each of components (e.g., the main processor 1100 or the GPU cores 1500) to operate smoothly. The electronic system 1000 which is illustrated in FIG. 12 and is described with reference to FIG. 12 may include some or all of the above components, and the present disclosure is not limited to some embodiments in which all the above components are included. For example, the electronic system 1000 may not include the user interface 1200 or the NVMs 1600.

According to embodiments of the present disclosure, a memory system capable of reducing a current consumption amount of a memory device and improving performance is provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An operation method of a high bandwidth memory (HBM) device, the method comprising:
receiving a mode register set (MRS) command through row command/address signal lines in an idle mode;
performing an MRS operation in response to the MRS command;
receiving an activate (ACT) command through the row command/address signal lines in the idle mode; and
switching to an activate mode in response to the ACT command,
wherein switching to the activate mode comprises switching one or more memory buffers of the HBM device to an active state.

2. The method of claim 1, wherein the HBM device includes a column command/address (CA) buffer configured to buffer column command/address signals, and
wherein, in the idle mode, the column CA buffer is in an inactive state such that current does not flow in the column CA buffer.

3. The method of claim 2, further comprising:
changing a state of the column CA buffer to an active state in which current flows therein, in response to the ACT command.

4. The method of claim 3, wherein the MRS operation comprises:
decoding the MRS command; and
performing the MRS operation based on a decoding result of the decoding of the MRS command.

5. The method of claim 3, further comprising:
receiving a precharge command in the activate mode; and
performing a precharge operation in response to the precharge command and switching to the idle mode.

6. The method of claim 5, wherein the HBM device further comprises a row CA buffer configured to buffer row command/address signals, and
wherein, in the idle mode and in the activate mode, the row CA buffer is in the active state.

7. The method of claim 3, further comprising:
performing, by the HBM device, a read operation of data in the activate mode.

8. An operation method of an high bandwidth memory (HBM) device, the method comprising:
selecting one of a first mode and a second mode in an idle mode, wherein a column command/address (CA) buffer configured to buffer a column command/address signal is in an inactive state in the first mode and is in an active state in the second mode;
performing a mode register set (MRS) operation in the idle mode; and
in the idle mode, receiving an activate (ACT) command through a row command/address signal line and switching to activate mode in response to the ACT command,
wherein switching to the activate mode comprises setting one or more memory buffers of the HBM device to the active state.

9. The method of claim 8, wherein the MRS operation is performed in response to a MRS command, the method further comprising:
receiving, in the first mode, the MRS command through the row command/address signal line.

10. The method of claim 8, wherein the performing of the MRS operation in the idle mode includes:
receiving an MRS command through a column command/address signal line; and
performing the MRS operation in response to the MRS command.

11. The method of claim 8, further comprising:
receiving, from a memory controller that is configured to control the HBM device, a control signal; and
switching between the first mode and the second mode in response to the control signal received from the memory controller.

12. The method of claim 9, further comprising:
changing a state of the column CA buffer to an active state in response to the ACT command.

13. The method of claim 9, further comprising:
receiving a precharge command in the activate mode; and
performing a precharge operation on the HBM device in response to the precharge command and switching to the idle mode.

14. The method of claim 9, wherein the HBM device includes a row CA buffer configured to buffer a row command/address signal, and
wherein, in the idle mode and the activate mode, the row CA buffer is in the active state.

15. A high bandwidth memory (HBM) device which is configured to store data, comprising:
a row command buffer configured to buffer a row command/address signal;
a column command buffer configured to buffer a column command/address signal;
a command/address (CA) buffer configured to decode the row command/address signal and the column command/address signal; and
a memory cell array configured to store the data,
wherein the HBM device is configured to receive a mode register set (MRS) command and an activate (ACT) command through the row command/address signal, and
wherein the ACT command indicates switching one or more memory buffers of the HBM device to active state.

16. The HBM device of claim 15, wherein, in an idle mode, the column command buffer is configured to be in an inactive state such that current does not flow in the column command buffer.

17. The HBM device of claim 16, wherein the HBM device is configured to switch to an activate mode responsive to the ACT command, and
wherein, in the activate mode, the HBM device is configured to switch to the idle mode responsive to a precharge command.

18. The HBM device of claim 16, wherein, in an activate mode, the column command buffer is configured to be in an active state.

19. The HBM device of claim 16, wherein, in the idle mode and in an activate mode, the row command buffer is configured to be in an active state.

20. The HBM device of claim 19, wherein, in the activate mode, the HBM device is configured to perform a read operation of the data.
